(19) United States
(12) Patent Application Publication
(10) Pub. No.: US 2008/0265881 A1
(43) Pub. Date: Oct. 30, 2008

(54) Direction Control Apparatus

(76) Inventors: Yung-Hsin Chang, Taipel (TW); Hsi-Zhen Lin, Taipel (TW)

Correspondence Address: LIN & ASSOCIATES INTELLECTUAL PROPERTY, INC., P.O. BOX 2339, SARATOGA, CA, 95070-0339, US

(21) Appl. No.: 12/108,491

(22) Filed: Apr. 23, 2008

(30) Foreign Application Priority Data
Apr. 26, 2007 (TW) 96114761

(51) Int. Cl. G01R 33/07

(52) U.S. Cl. 324/251

(57) ABSTRACT

A direction control apparatus is provided. The direction control apparatus includes an input unit, and a magnetic sensing unit. The input unit includes an operation member, a magnetic member, an elastic member, and a base. The elastic member is an elastic structure. The magnetic sensing unit includes a magnetic sensor, and a magnetic signal processing device. The magnetic sensor is a device for sensing a distribution of a magnetic field, and the magnetic signal processing device is an electronic calculating device. The elastic member is provided for restricting the operation member at either a first status position or a second status position. When at the first status position, the operation member is positioned at balanced position where the elastic member achieves an elastic balance.

### BACKGROUND OF THE INVENTION

1. Field of the Invention

The present invention relates generally to a direction control apparatus, and more particularly, to provide an operation mechanism producing a magnetic field, and an apparatus for sensing a distribution of the magnetic field, so as to output an electrical data of a translation amount.

2. The Prior Arts

Direction control apparatuses are often employed by electronic apparatuses such as computers, cell phones, and personal digital assistants (PDA), for serving as input devices controlled by cursors or menu type operational interfaces. Typically, conventional direction control apparatuses are often configured as mice, track balls, or directional keys/icons of electronic products. However, such a direction control apparatuses usually achieves direction control and selection via sophisticated mechanical structures, and is therefore often configured with a large volume, which is contradicted to the trend of portability and miniaturization for the current electronic products.

Further, there are also provided a kind of direction control apparatuses featured by the employment of force feedback therein. Such a direction control apparatus identifies an input direction according to the direction from which the user applies a pressure. However, in order to agilely and accurately control the input direction, the user must sensitively apply the pressure. In this manner, an ordinary user may feel inconvenient in operating such a direction control apparatus for input directions.

As such, a direction control apparatus is desired to be provided for providing a solution in accordance with the foregoing disadvantages of the conventional direction control apparatuses.

### SUMMARY OF THE INVENTION

A primary objective of the present invention is to provide a direction control apparatus. The direction control apparatus is featured by a magnetic sensing principle and is adapted for sensing a displacement direction and a displacement amount of a direction input mechanism, and therefore is configured with a relative small size.

Another objective of the present invention is to provide a direction control apparatus having a switch device. The direction input mechanism is adapted to control whether to trigger the switch device, so that a trigger signal of the switch device can be taken as a control signal for confirming an input.

A further objective of the present invention is to provide a direction control apparatus having a calibration initial value. The calibration initial value is adapted for calibrating an initial error caused by the direction input mechanism of the direction control apparatus via a magnetic signal processing apparatus of the direction control apparatus, so as to more stably input the direction.

For achieving the foregoing objectives, the present invention provides a direction control apparatus. The direction control apparatus includes an input unit, and a magnetic sensing unit. The input unit includes an operation member, a magnetic member, an elastic member, and a base. The operation member includes a contact region configured at an upper surface thereof. The magnetic member is a magnetic unit disposed at the operation member. The elastic member is an elastic structure. The magnetic sensing unit includes a magnetic sensor, and a magnetic signal processing device. The magnetic sensor is a device for sensing a distribution of a magnetic field, and the magnetic signal processing device is an electronic calculating device. The displacement direction and the displacement amount of the operation member are selected by pushing the contact region to move. A peripheral of the elastic member is fixed to the base, and an inside of the elastic member is fixed to the operation member. The elastic member is provided for restricting the operation member at either a first status position or a second status position. When at the first status position, the operation member is positioned at balanced position where the elastic member achieves an elastic balance. When at the second status position, the operation member is moved away from the balanced position. The magnetic sensor is electrically connected to the magnetic signal processing device. The magnetic field distribution data obtained by the magnetic sensor is transmitted to the magnetic signal processing device. The magnetic signal processing device converts the magnetic field distribution data obtained by the magnetic sensor and outputs an electrical data corresponding to the displacement of the operation member. The electrical data outputted from the magnetic signal processing device corresponding to the displacement of the operation member includes the direction and the amount of the displacement of the operation member.

According to an embodiment of the present invention, the elastic member is an elastic structure made of a rubber material, for restricting the operation member at either the first status position or the second status position.

According to an embodiment of the present invention, the magnetic sensor further includes a plurality of Hall components disposed in an electrical substrate with a certain layout. The magnetic signal processing device is configured in a circuit form of a chip and is disposed in the electrical substrate.

According to an embodiment of the present invention, the direction control apparatus further includes an interface unit, electrically connected to a data transmittance interface of the magnetic signal processing device, and adapted for converting the electrical data outputted from the magnetic signal processing device according to a data transmittance protocol, and outputting an electrical data defined according to the data transmittance protocol.

According to an embodiment of the present invention, the direction control apparatus further includes a switch device. The switch device is a push type device for generating a trigger signal. The switch device is disposed corresponding to a displacement path of the operation member, and can be selected by the operation member to switch between a trigger-on status and a trigger-off status. The switch device is disposed at the electrical substrate and corresponding to the displacement path of the operation member. Further, the elastic member of the input unit is adapted for deforming along a vertical direction, and can be deformed with a tolerate deforming amount in the vertical direction which allows the operation member of the input unit moving along the displacement path to contact and trigger the switch device.

The magnetic signal processing device is adapted for comparing a position data of a displacement of the operation member at the second status with a position data of a displacement of the operation member at the first status, and outputting an electrical data corresponding to the displacement of the operation member at the second status. The electrical data corresponding to the displacement of the operation member at the second status outputted from the magnetic signal processing device includes a translation direction of the operation member. The electrical data corresponding to the displacement of the operation member at the second status outputted from the magnetic signal processing device further includes a translation distance of the operation member.

Accordingly, the present invention is advantageously adapted for: decreasing the entire volume of the direction control apparatus; providing the trigger signal of the switch device serving as a control signal for confirming an input; and calibrating an initial error caused by the direction input mechanism and obtaining a more stable direction input data.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram illustrating a correlation between components of a direction control apparatus according to an embodiment of the present invention;

FIG. 2 is a perspective view of a direction control apparatus according to an embodiment of the present invention;

FIG. 3 is a cross-sectional view taken along line III-III of FIG. 2; and

FIG. 4 is a top view of the direction control apparatus according to an embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

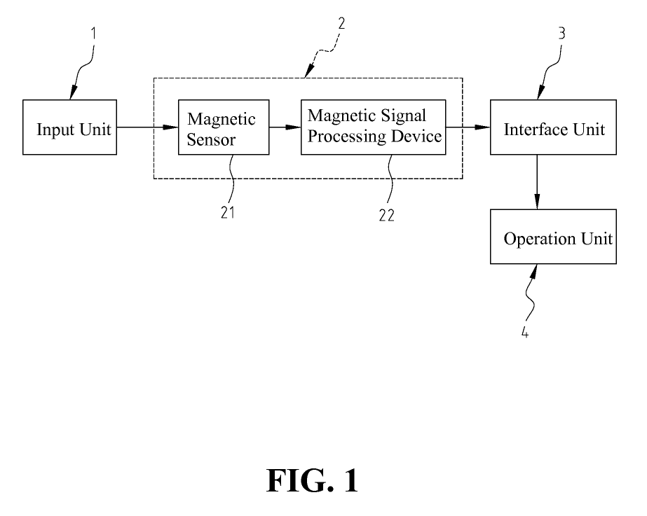

Referring to FIG. 1, there is shown a schematic diagram illustrating a correlation between components of a direction control apparatus according to an embodiment of the present invention. The direction control apparatus according to the embodiment of the present invention mainly includes an input unit 1 incorporating with a magnetic sensing unit 2. The input unit 1 generates a magnetic field, and the magnetic sensing unit 2 senses the magnetic field and outputs a position control data corresponding to the magnetic field. The magnetic sensing unit 2 transmits the position control data via an interface unit 3 to an operation unit 4. In such a way, the position control data is provided to the operation unit 4 for performing a corresponding calculation.

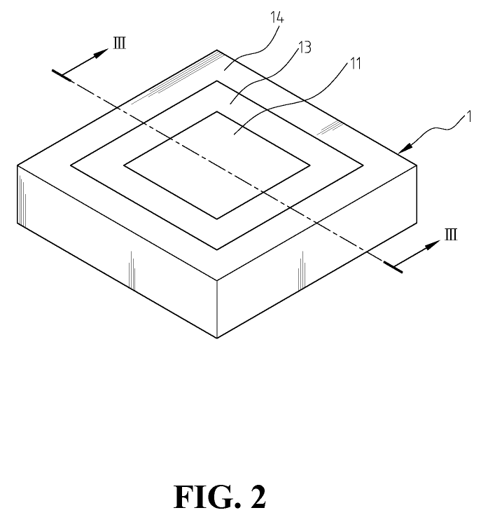

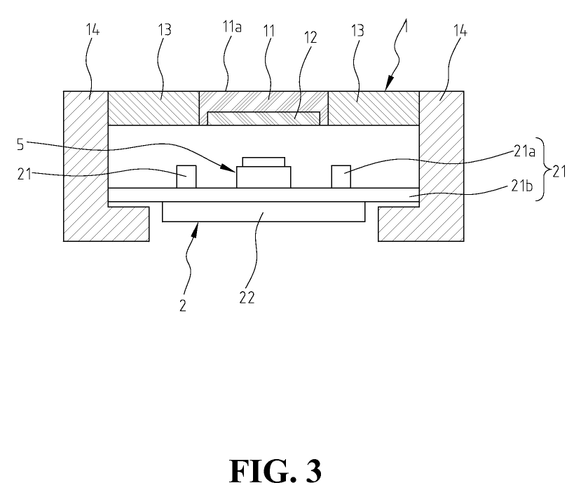

FIG. 2 is a perspective view of a direction control apparatus according to an embodiment of the present invention. FIG. 3 is a cross-sectional view taken along line III-III of FIG. 2. Referring to FIGS. 2 and 3 together, the input unit 1 includes an operation member 11, a magnetic member 12, an elastic member 13, and a base 14. The operation member 11 includes a contact region 11a configured at an upper surface thereof. The contact region 11a is provided for allowing a user to contact and push the operation member 11 to move. The magnetic member 12 is a magnetic component producing a magnetic field. The magnetic member 12 is disposed at a bottom of the operation member 11. The elastic member 13 is an elastic component adapted for producing an elastic force. A peripheral of the elastic member 13 is fixed to the base 14, and an inside of the elastic member 13 is fixed to the operation member 11, so that when the operation member 11 is not pushed by the user, the operation member 11 stays at a balanced position.

The elastic member 13 is made of a rubber material, or a material adapted for producing a suitable elastic force. The operation member 11 is disposed at a central position of the elastic member 13, so that the operation member 11 usually stays at a central balance position of the elastic member 13. When the user pushes the contact region 11a of the operation member 11 to move, the elastic member 13 generates an elastic deformation, and when the user releases the operation member 11, the elastic member 13 recovers back to an initial balanced status, and drives the operation member 11 back to the central balanced position of the elastic member 13.

The magnetic sensing unit 2 includes a magnetic sensor 21, and a magnetic signal processing device 22. The magnetic sensor 21 is a device for sensing a distribution of a magnetic field. When the operation member 11 is pushed to move, the magnetic sensor 21 is adapted to sense a distribution of the magnetic field generated by the magnetic member 12 so as to obtain a magnetic field distribution data. The magnetic signal processing device 22 is an electronic calculating device adapted for converting the magnetic field distribution data obtained by the magnetic sensor 21 into a vector data corresponding to a displacement of the operation member 11 for outputting.

In details, the magnetic sensor 21 preferably includes a plurality of Hall components 21a disposed in an electrical substrate 21b with a certain layout. Each of the magnetic signal processing devices 22 is a semiconductor component having a Hall Effect. The electrical substrate 21b is electrically connected with the Hall components 21a and the magnetic signal processing device 22, and fixes the same thereto. In such a way, the Hall components 21a respectively sense corresponding magnetic fields and output corresponding electrical data to the magnetic signal processing device 22. The electrical data outputted by the Hall components 21a as a whole serve as the magnetic field distribution data

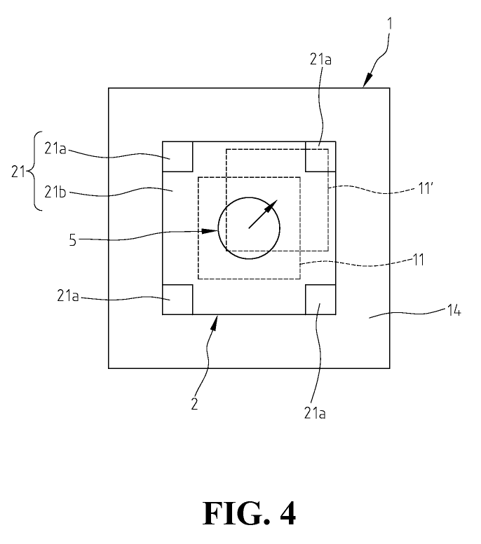

FIG. 4 is a top view of the direction control apparatus according to the embodiment of the present invention as discussed above. Referring to FIG. 4, according to the embodiment, when the operation member 11 initial stays at the balanced position, the operation member 11 is defined as being at a first status, and when the operation member 11 is pushed to move to a stopping position (at where the operation member 11 is represented by a dashed figure marked with 11′ for identification purpose), the operation member 11′ is defined as being at a second status. When the operation member 11 is pushed to move so that the operation member 11 is changed from the first status to the second status, the Hall components 21a respectively sense the magnetic fields generated by the magnetic member 12 disposed at the bottom of the operation member 11′. In such a way, the Hall components 21a sense different magnetic fields of different strengths in accordance with the magnetic field distribution generated by the magnetic member 12. Therefore, the Hall components 21a respectively sense corresponding magnetic fields and output corresponding electrical data. Then, the magnetic signal processing device 22 converts the electrical data outputted from the Hall components into a data corresponding to a displacement of the operation member 11′ for outputting.

According to an aspect of the embodiment, the magnetic signal processing device 22 is configured in a circuit form of a chip, and the displacement data of the operation member 11 outputted from the magnetic signal processing device 22 includes a displacement direction of the operation member. According to a further aspect of the embodiment, the displacement data of the operation member 11 outputted from the magnetic signal processing device 22 is a displacement vector data including a displacement direction and a displacement amount of the operation member 11.

Further, the interface unit 3 is a data transmittance interface, for converting the vector data outputted from the magnetic signal processing device 22 of the magnetic sensing unit into a certain data transmittance protocol, and outputting the data transmittance protocol to the operation unit 4. The operation unit 4 is an electronic system. When the interface unit 3 transmits the vector data outputted from the magnetic sensing unit 2 to the operation unit 4, the operation unit 4 performs a corresponding data calculation, and generates an output data.

In more details, for example, the operation unit 4 is a personal computer (PC), and the displacement direction of the operation member 11 included in the vector data outputted from the magnetic signal processing device 22 is accorded for the operation unit 4 in controlling a moving direction of a cursor in a window operation system. Further, the displacement amount of the operation member 11 included in the vector data outputted from the magnetic signal processing device 22 is accorded for the operation unit 4 in controlling a moving speed of a cursor in a window operation system.

The operation unit 4 can also be other kind of electronic apparatuses, and the vector data provided by the magnetic sensing unit 2 is provided for the operation unit 4 for performing a corresponding calculation, so that the operation of the input unit 1 in combination with the data feedback of the magnetic sensing unit 2 is capable of replacing a key, a directional key, or any apparatus providing direction selection function used by ordinary electronic products.

Referring to FIG. 3 again, the direction control apparatus according to the present invention further includes a switch member 5. The switch device 5 is a push type device for generating a trigger signal. The switch device 5 is disposed in the electrical substrate 21b of the magnetic sensing unit 2 and corresponding to the operation member 11. Further, the elastic member 13 of the input unit 1 is adapted for deforming along a vertical direction, and can be deformed with a tolerate deforming amount in the vertical direction which allows a bottom of the operation member 11 of the input unit 1 moving along the displacement path to contact and trigger the switch device 5. In details, in operation, the operation member 11 is pushed, and therefore the operation member 11 triggers the switch device 5. Generally, such a mechanism can be taken for the operation unit 4 as a trigger signal for data entering.

Referring to FIG. 4 again, in the embodiment of the direction control apparatus according to the present invention, when the operation member 11 is at the defined first status and stays at the initial balanced position, the Hall components 21a respectively sense the magnetic fields generated by the magnetic member 12 at the bottom of the operation member 11. According to the distribution of the magnetic fields generated y the magnetic member 12, the Hall components 21a sense magnetic fields of different magnetic strengths, so that each of the Hall components 21a outputs an electrical data corresponding to the strength of the sensed magnetic field. When the operation member 11 is at the first status, the magnetic signal processing apparatus 22 is adapted to convert the electrical data outputted by the Hall components 21a into data corresponding to the displacement of the operation member 11 for outputting, and the position of the operation member 11 is defined as an initial position. Specifically, the magnetic signal processing device 22 is adapted to subtract a coordinate of the position of the operation member 11 at the first status from a coordinate of the position of the operation member 11′ at the second status, so as to obtain a vector data. A direction of the vector data is a translation direction of the operation member 11, and a length of the vector data is a translation distance of the operation member 11. In practical operation, a moving direction of the cursor in the operation system of the operation unit 4 is determined corresponding to the direction of the vector data, and a moving speed of the cursor can be determined corresponding to the length of the vector data. Further, a signal shift caused by a signal error due to structural deformation in the input unit 1 can be eliminated by fetching the translation vector data of the operation member 11. Specifically, upon the assumption of an occurrence of a partial permanent deformation of the elastic member 13, when the operation member 11 is not pushed by the user, the direction and the length of the translation vector data of the operation member 11 are all 0, and therefore there won't be any erroneous direction input data generated by the direction control apparatus according to the present invention.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A direction control apparatus, comprising:
an input unit, comprising:
an operation member, having a contact region configured at an upper surface thereof,
a magnetic member, being a magnetic unit disposed at the operation member;
an elastic member, being an elastic structure; and
a base; and
a magnetic sensing unit, comprising:
a magnetic sensor, being a device for sensing a distribution of a magnetic field; and
a magnetic signal processing device, being an electronic calculating device,
wherein a direction and an amount of a displacement of the operation member are selected by pushing the contact region to move; a peripheral of the elastic member is fixed to the base, and an inside of the elastic member is fixed to the operation member; the elastic member is adapted for restricting the operation member at either a first status position or a second status position, wherein when at the first status position, the operation member is positioned at a balanced position where the elastic member achieves an elastic balance, and when at the second status position, the operation member is pushed to move away from the balanced position, and wherein the magnetic sensor is electrically connected to the magnetic signal processing device; a magnetic field distribution data obtained by the magnetic sensor is transmitted to the magnetic signal processing device; and the magnetic signal processing device converts the magnetic field distribution data obtained by the magnetic sensor and outputs an electrical data corresponding to the displacement of the operation member.

2. The direction control apparatus according to claim 1, wherein the magnetic sensor further comprises a plurality of Hall components disposed in an electrical substrate with a certain layout.

3. The direction control apparatus according to claim 2, wherein the magnetic signal processing device is disposed in the electrical substrate.

4. The direction control apparatus according to claim 3, wherein the magnetic signal processing device is configured in a circuit form of a chip.

5. The direction control apparatus according to claim 1, further comprising an interface unit, electrically connected to a data transmittance interface of the magnetic signal processing device, and adapted for converting the electrical data outputted from the magnetic signal processing device according to a data transmittance protocol, and outputting an electrical data defined according to the data transmittance protocol.

6. The direction control apparatus according to claim 1, further comprising a switch device, wherein the switch device is a push type device for generating a trigger signal, and the switch device is disposed corresponding to a displacement path of the operation member, and is selected by the operation member to switch between a trigger-on status and a trigger-off status.

7. The direction control apparatus according to claim 6, wherein the magnetic sensor comprises a plurality of Hall components and an electrical substrate, wherein the Hall components are disposed in the electrical substrate with a certain layout, and the switch device is disposed at the electrical substrate and corresponding to the displacement path of the operation member.

8. The direction control apparatus according to claim 7, wherein the elastic member of the input unit is adapted for deforming along a vertical direction, and can be deformed with a tolerate deforming amount in the vertical direction which allows the operation member of the input unit moving along the displacement path to contact and trigger the switch device.

9. The direction control apparatus according to claim 1, wherein the elastic member is an elastic structure composed of a rubber material.

10. The direction control apparatus according to claim 1, wherein the electrical data outputted from the magnetic signal processing device corresponding to the displacement of the operation member includes the direction and the amount of the displacement of the operation member.

11. The direction control apparatus according to claim 1, wherein the magnetic signal processing device is adapted for comparing a position data of the displacement of the operation member at the second status with a position data of the displacement of the operation member at the first status, and outputting an electrical data corresponding to the displacement of the operation member at the second status.

12. The direction control apparatus according to claim 11, wherein the electrical data corresponding to the displacement of the operation member at the second status outputted from the magnetic signal processing device comprises a translation direction of the operation member.

13. The direction control apparatus according to claim 11, wherein the electrical data corresponding to the displacement of the operation member at the second status outputted from the magnetic signal processing device further comprises a translation distance of the operation member.
